(19) United States
(12) Patent Application Publication
(10) Pub. No.: US 2008/0024184 A1
(43) Pub. Date: Jan. 31, 2008

(54) FLIP-FLOP HAVING IMPROVED SET-UP TIME AND METHOD USED WITH

(75) Inventor: Hsin-Shih Wang, Fremont, CA (US)

Correspondence Address: J C PATENTS, INC., 4 VENTURE, SUITE 250, IRVINE, CA, 92618, US

(73) Assignee: FARADAY TECHNOLOGY CORP., Hsinchu (TW)

(21) Appl. No.: 11/460,472

(22) Filed: Jul. 27, 2006

(51) Int. Cl. H03K 3/289

(52) U.S. Cl. 327/202

(57) ABSTRACT

A flip-flop having improved set-up time and a method used with are provided. The flip-flop comprises a first master latch, a first selector, a second master latch, a second selector, and a slave latch. The first master latch receives the critical data and is used to latch the critical data. The first selector receives a plurality of non-critical data and outputs a first selected data to the second latch. The second master latch is used to latch the first selected data. The second selector is coupled to the first master latch and the second master latch in order to output a second selected data to the slaver latch. The slave latch is used to latch and output the second selected data.

### BACKGROUND OF THE INVENTION

1. Field of Invention

The present invention relates to a flip-flop and a method used with. More particularly, the present invention relates to a flip-flop having an improved set-up time and a method used with.

2. Description of Related Art

With the development of design and the technique of integrated circuits, the circuit performance has been greatly improved. This can be seen from an example in the field of the microprocessor. Only a couple of years ago, personal computer microprocessors were still at the clock of 300 MHZ (megahertz), and now, the personal computer microprocessors have achieved 3000 MHZ or higher. Therefore, the speed and the delay of the clock have an enormous impact on the circuit performance.

FIG. 1 is a circuit block diagram of a typical delay path in a digital circuit. The delay path is widely applied to microprocessors and other digital circuits. A conventional path includes flip-flops 101, 103 and a combinational logic unit 102. As shown in the figure, in the flip-flops 101, 103, D is the data input end, Q is the data output end, and CK is the clock signal receiving end. The flip-flops 101, 103 are controlled by the clock signal. FIG. 2 is a clock diagram of the operating delay of FIG. 1. Referring to FIG. 1 and FIG. 2, during the first positive triggering of the clock signal, the flip-flop 101 releases data to the combinational logic unit 102. At this time, before the data is exactly displayed by the flip-flop 101, a delay time interval 204 of the CK-Q (clock versus output value) occurs. Once the data is generated by the flip-flop 101, it is input into the flip-flop 103 though the combinational logic unit 102, and the time interval for transmitting the data in the combinational logic unit 102 is the transmitting time interval 205. Moreover, the set-up time interval 206 is in a relationship with the state setting of the flip-flop 101. Therefore, the delay can be considered to be the sum of the delay time interval 204, the transmitting time interval 205, and the set-up time interval 206.

FIG. 3 is a circuit block diagram of the conventional master-salve type flip-flop. The data and the time data are input to the NOR gate 313 through the AND gates 311 and 312, and the select signal controls the output value of the AND gates 311 and 312 through the inverter 301. The NOR gate 313 is coupled to the master latch MFF. The clock signal outputs a clock signal CK30 and clock signal CK31 through the inverters 308 and 309. The clock signals CK30 and CK31 control the switches 321, 322 of the master flip-flop MFF and the switches 323, 324 of the slave flip-flop SFF, so as to perform the conversion between latching the signal and outputting the signal. The inverters 302, 303 and the inverters 304, 305 perform latching the signal, and the inverters 306, 307 invert the output signal of the slave latch SFF.

Since the generating time of each of the signals is different, for example, the generating time of the non-critical data, e.g. scan_in (scanning in) signal and the feedback signal are shorter than the generating time of the critical data. The conventional circuit in FIG. 3 inputs all the data into the same master latch MFF, and then to the slave latch SFF. Thus, the critical data and the non-critical data must share the same circuit and clock, such that the optimal clock cannot be achieved.

### SUMMARY OF THE INVENTION

Accordingly, an objective of the present invention is to provide a flip-flop having an improved set-up time, in which different master latches are used to latch the critical data and the non-critical data, so as to improve the set-up time of the flip-flop and the time sequence of the critical path.

Another objective of the present invention is to provide a method used with the flip-flop having improved set-up time, the critical data and the non-critical data can be separately processed to improve the set-up time of the flip-flop and the time sequence of the critical path.

The present invention provides a flip-flop having improved set-up time, which comprises a first maser latch, a first selector, a second master latch, a second selector, and a slave latch. A first master latch receives a critical data and is used to latch the critical data. The first selector receives a plurality of non-critical data and selectively outputs a first selected data. The second master latch is coupled to the first selector and receives the first selected data and is used to latch the first selected data. A first input end of the second selector is coupled to the first master latch, and a second output end of the second selector is coupled to the second master latch. And the slave latch is coupled to the second selector, wherein the second selector receives the critical data or the first selected data and outputs a second selected data to the slave latch, and the slave latch is used to latch and output the second selected data.

The present invention further provides a method used with the flip-flop having improved set-up time, which comprises: first receiving a plurality of non-critical data and selecting one of the non-critical data to be a first selected data, latching the first selected data, and receiving and latching a critical data in sync. Next, the critical data or the first selected data is selected to be a second selected data. Then, the second selected data is latched and output.

In view of the preferred embodiment, the generating time of each of the plurality of non-critical of the flip-flop is shorter than the generating time of the critical data.

In the present invention, the critical data and the non-critical data are separated and latched, and the selector is adopted to select the latched critical data and the latched non-critical data, such that the critical data and the non-critical data are separately processed without affecting each other. Therefore, the set-up time of the flip-flop and the time sequence of the critical path can be improved.

In order to make the aforementioned and other objects, features and advantages of the present invention comprehensible, preferred embodiments accompanied with figures are described in detail below.

### BRIEF DESCRIPTION OF THE DRAWINGS

FIG. 1 is a circuit block diagram of a typical delay path in a digital circuit.

FIG. 2 is a clock diagram of the operating delay of the circuit block of FIG. 1.

FIG. 3 is a circuit block diagram of the conventional master-salve type flip-flop.

FIG. 4 is a circuit block diagram of the flip-flop having improved set-up time according to an embodiment of the present invention.

FIG. 5 is a circuit block diagram of the flip-flop having improved set-up time according to another embodiment of the present invention.

FIG. 6 is the method used with the flip-flop having improved set-up time according to an embodiment of the present invention.

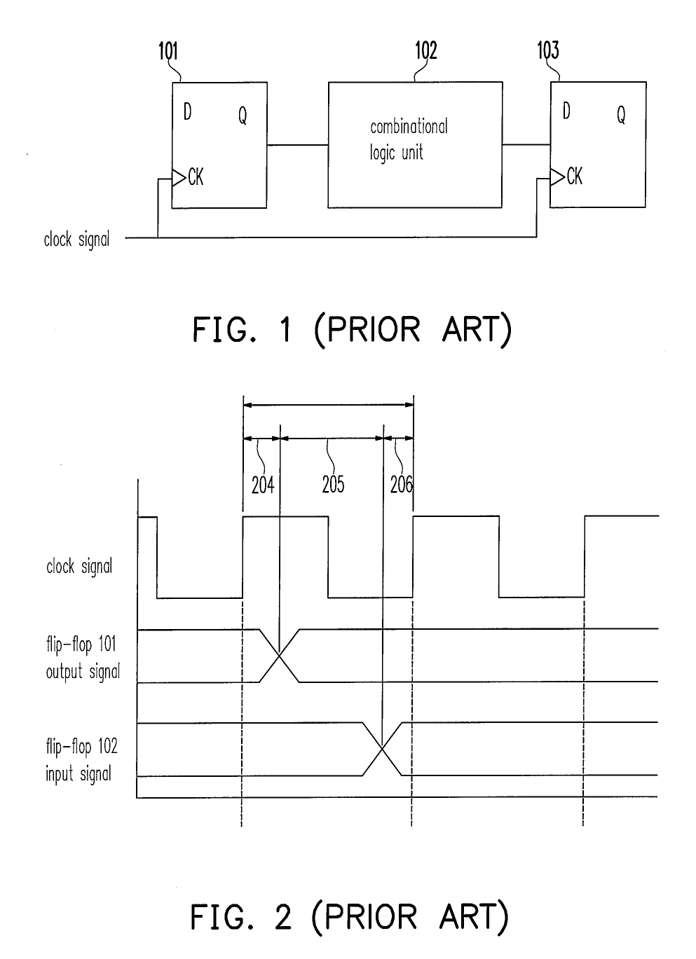

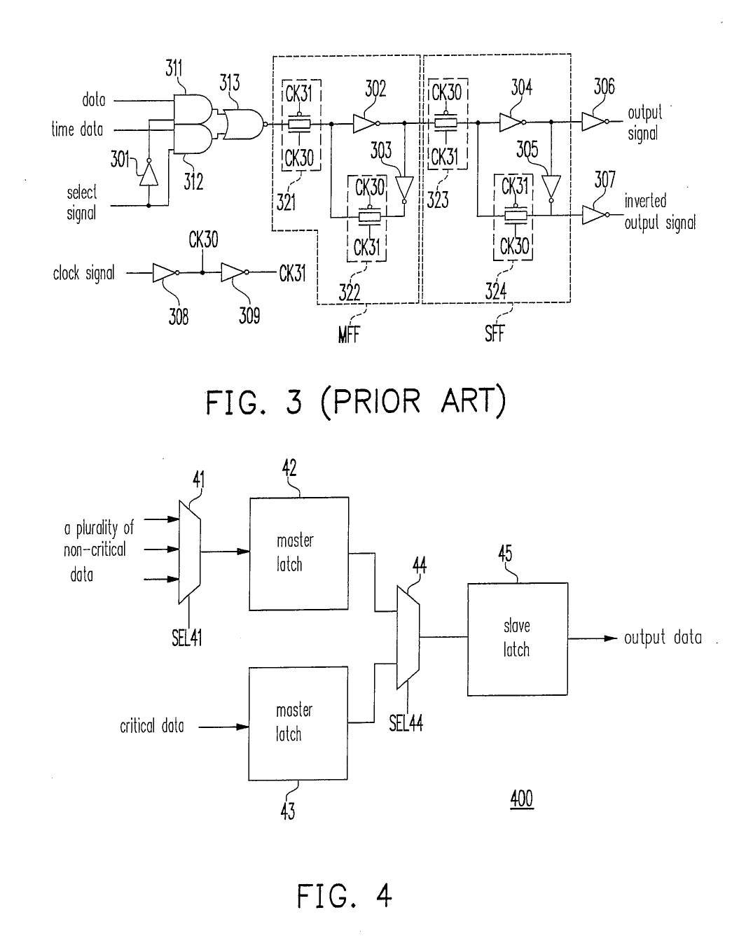

### DESCRIPTION OF EMBODIMENTS

FIG. 4 is a circuit block diagram of the flip-flop having improved set-up time according to an embodiment of the present invention. The flip-flop having improved set-up time 400 comprises selectors 41 and 44, master latches 42 and 43, and a slave latch 45. The control signal SEL41 controls the selector 41, such that after the plurality of non-critical data such as the non-critical data scan_in (scanning in) signal and the feedback signal are selected by the selector 41, one of the plurality of non-selective data is output to be a first selected data to the master latch 42, and the master latch 42 latches the first selected data. The critical data is input and stored to be latched in the maser latch 43. And the generating time of each of the non-critical data is shorter than the generating time of the critical data. The selector 44 receives the first selected data of the maser latch 42 and the critical data of the maser latch 43. The control signal SEL44 controls the selector 44 to output the second selected data, and the second selected data is input to the slave latch 45. Then the slave latch 45 latches second selected data the data and exports an output data.

The present invention uses two different master latches to separately process the critical data and the non-critical data, such that it is not required for the flip-flop to achieve the unification of the clock for the process of the critical data and the non-critical data. Further, the non-critical data with the shorter generating time quickly passes through the selector to the slave latch. Since the function of separate processing makes the slave latch process the non-critical data first, which is help to reduce the set-up time of the flip-flop.

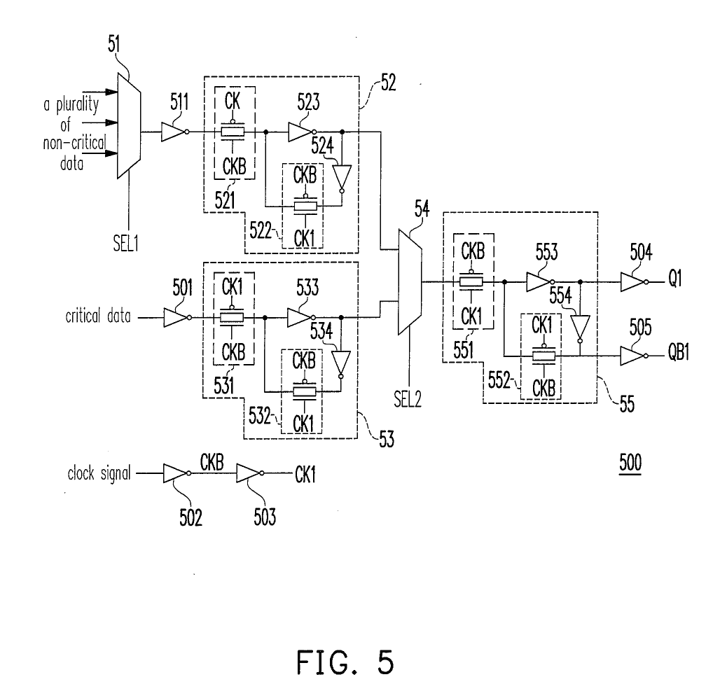

FIG. 5 is a circuit block diagram of the flip-flop having improved set-up time according to another embodiment of the present invention. The flip-flop 500 comprises a selector 51, a positive latch 52, a positive latch 53, a selector 54, a slave latch 55, and inverters 501˜505, 511. A plurality of non-critical data passes through the selector controlled by the select signal SEL1, and a first select signal is input to the master latch 52 by the inverter 511. The master latch 52 comprises switches 521, 522 and inverters 523, 524. The switch 521 controls the master latch 52 to receive the first selected data, and the first selected data is latched by the inverters 523, 524 and the switch 522 through the twice inverting mechanism, and then the non-critical data is input to the selector 54. The clock signal CK generates a clock signal CKB through the inverter 502, and generates a clock signal CK1 through the inverter 503. The clock signal CKB and the clock signal CK1 are used to control the ON/OFF of the switch 521 and the switch 522. The master 52 can perform the latching function with this structure, and the critical data is inverted by the inverter 501 and input to the master latch 53. The master latch 53 has a structure same as that of the master latch 52. The master latch 522 comprises switches 531, 532 and inverters 533, 534, and is used to latch and output the inverted critical data to the selector 54.

The selector 54 receives the first selected data of the maser latch 52 and the critical data of the master latch 53. The selector 54 outputs the second selected data to the slave latch 55 through the control of the select signal SEL2. The slave latch 55 has a structure same as that of the master latch 52, and the slave latch 55 comprises switches 551, 552 and inverters 553, 554. The slave latch 55 latches the second selected data, and receives the second selected data through the inverters 504, 505, so as to generate the output signal Q and the inverted output signal QB.

The present invention uses a select signal to control a selector to filter the plurality of non-critical data, and uses another select signal to control another selector to filter the critical data and the non-critical data. Thus, the non-critical data and the critical data can be separately processed, and not required to follow the same clock, thereby enhancing the processing speed.

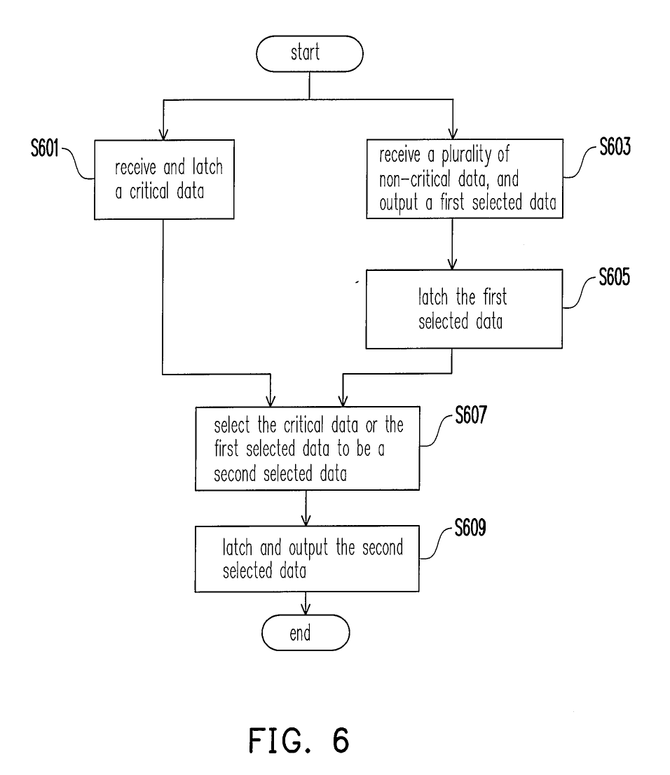

FIG. 6 is the method used with the flip-flop having improved set-up time according to an embodiment of the present invention. First, in step S601, a critical data is received and latched. At the same time, in step 603, a plurality of non-critical data is received, and a first selected data is output. Then, in step S605, the first selected data is latched. Next, in step S607, the critical data or the first selected data is selected to be a second selected data. In step S609, the second selected data is latched and output.

To sum up, according to the flip-flop having improved set-up time and the method used with provided by the present invention, since two different master latches are used with the selector to separately process the critical data and the non-critical data, such that the critical data and the non-critical data can be latched by different master latches without affecting each other, thereby improving the set-up time of the flip-flop and the time sequence of the critical path.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A flip-flop having improved set-up time, comprising:
a first master latch receiving a critical data and being used to latch the critical data;
a first selector receiving a plurality of non-critical data and outputting one of a plurality of non-critical data to be a first selected data;
a second master latch coupled to the first selector and being used to latch the first selected data;
a second selector coupled to the first master latch and the second master latch; and
a slave latch coupled to the second selector, wherein the second selector is used to select the critical data and the first selected data to output a second selected data to the slave latch, and the slave latch is used to latch and output the second selected data.

2. The flip-flop having improved set-up time as claimed in claim 1, wherein the first master latch comprises a first switch, a second switch, a first inverter, a second inverter, and the first switch is used to control the input of the critical data, the first inverter is coupled to the second inverter through the second switch, so as to latch and output the critical data.

3. The flip-flop having improved set-up time as claimed in claim 1, wherein the second master latch has a construction same as that of the first master latch.

4. The flip-flop having improved set-up time as claimed in claim 1, wherein the slave latch has a construction same as that of the first master latch.

5. The flip-flop having improved set-up time as claimed in claim 1, wherein the generating time of each of the non-critical data is shorter than the generating time of the critical data.

6. A method used in the flip-flop having improved set-up time, comprising:
receiving a plurality of non-critical data, and selecting one of the non-critical data to be a first selected data, and latching the first selected data while receiving and latching a critical data;
selecting the critical data or the first selected data to be a second selected data; and
latching and outputting the second selected data.

7. The method used in the flip-flop having improved set-up time as claimed in claim 6, wherein the generating time of each of the non-critical data is shorter than the generating time of the critical data.
